(19) United States
(12) Patent Application Publication
(10) Pub. No.: US 2026/0083013 A1
(43) Pub. Date: Mar. 19, 2026

(54) CHIP-STACKED DEVICE AND METHOD FOR MANUFACTURING CHIP-STACKED DEVICE

(71) Applicant: NuFlare Technology, Inc., Yokohama-shi (JP)

(72) Inventors: Kazumichi TSUMURA, Shinagawa (JP); Kazuyuki HIGASHI, Yokohama (JP); Tomohiro SAITO, Yokohama (JP); Kei OBARA, Kawasaki (JP); Hideo INOUE, Miura (JP)

(73) Assignee: NuFlare Technology, Inc., Yokohama-shi (JP)

(21) Appl. No.: 19/272,005

(22) Filed: Jul. 17, 2025

(30) Foreign Application Priority Data
Sep. 18, 2024 (JP) 2024-160948

(51) Int. Cl. H10W 90/00; H10W 72/00; H10W 72/20; H10W 72/29; H10W 72/90

(52) U.S. Cl. CPC H10W 90/00; H10W 72/07232; H10W 72/221; H10W 72/234; H10W 72/237; H10W 72/248; H10W 72/29; H10W 72/926; H10W 72/936; H10W 90/722

(57) ABSTRACT

A chip-stacked device includes a first chip including a first substrate including a first face, a first conductive film provided in an island form over the first face and electrically connected to a signal line, and a second conductive film provided apart from the first conductive film over the first face and connected to the ground line; a second chip; a first bonding portion covering the first conductive film; and a second bonding portion apart from the first conductive film and the first bonding portion, the second bonding portion located over the second conductive film. The first chip and the second chip are bonded to each other via the first bonding portion and the second bonding portion.

### CROSS-REFERENCE TO RELATED APPLICATIONS

This application is based upon and claims the benefit of priority from Japanese Patent Application No.2024-160948, filed on Sep. 18, 2024; the entire contents of which are incorporated herein by reference.

### FIELD

Embodiments of the invention relate to a chip-stacked device and a method for manufacturing a chip-stacked device.

### BACKGROUND

A device in which two chips are stacked by metal-to-metal bonding is known.

### SUMMARY

An object of embodiments of the invention is to provide a chip-stacked device having an appropriate structure according to the function of a bonding portion and a method for manufacturing the chip-stacked device.

According to an embodiment of the invention, a chip-stacked device includes a first chip including a first substrate including a first face, a first conductive film provided in an island form over the first face and electrically connected to a signal line, and a second conductive film provided apart from the first conductive film over the first face and connected to the ground line; a second chip; a first bonding portion covering the first conductive film; and a second bonding portion apart from the first conductive film and the first bonding portion, the second bonding portion located over the second conductive film; wherein the first chip and the second chip are bonded to each other via the first bonding portion and the second bonding portion.

According to an embodiment of the invention, a chip-stacked device includes a first chip; a second chip including a second substrate including a second face, a third conductive film provided in an island form over the second face and electrically connected to the signal line, and a fourth conductive film provided apart from the third conductive film over the second face and connected to the ground line; a first bonding portion covering the third conductive film; and a second bonding portion apart from the third conductive film and the first bonding portion, the second bonding portion located over the fourth conductive film; wherein the first chip and the second chip are bonded to each other via the first bonding portion and the second bonding portion.

According to an embodiment of the invention, a method for manufacturing a chip-stacked device includes: preparing a first structure in which a plurality of first metal portions electrically connected to a signal line and a plurality of third metal portions electrically connected to a ground line are provided on a first face of a first substrate; preparing a second structure in which a plurality of second metal portions and a plurality of fourth metal portions are provided on a second face of a second substrate; and bonding the first metal portion and the second metal portion to each other and bonding the third metal portion and the fourth metal portion to each other by causing the first face and the second face to face each other in a first direction and applying a load in the first direction to the first structure and the second structure, a protruding portion is provided on a first bonding face of at least one of the first metal portion and the second metal portion, the first bonding face being bonded to another of the first metal portion and the second metal portion, and a step on a second bonding face of at least one of the third metal portion and the fourth metal portion, the second bonding face being bonded to another of the third metal portion and the fourth metal portion, is smaller than a step on the first bonding face.

### BRIEF DESCRIPTION OF THE DRAWINGS

FIG. 1 is a schematic cross-sectional view of a chip-stacked device according to a first embodiment;

FIG. 2 and FIG. 3 are schematic plan views of a first face side of a first substrate in the chip-stacked device according to the first embodiment;

FIG. 4 is a schematic cross-sectional view showing a method for manufacturing the chip-stacked device according to the first embodiment;

FIG. 5 is a schematic cross-sectional view of a chip-stacked device according to a second embodiment;

FIG. 6 is a schematic cross-sectional view of a chip-stacked device according to a third embodiment; and

FIG. 7 is a schematic cross-sectional view of a chip-stacked device according to a fourth embodiment.

### DETAILED DESCRIPTION

### Embodiments Will Now Be Described With Reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

The same or similar elements are denoted by the same reference numerals.

### First Embodiment

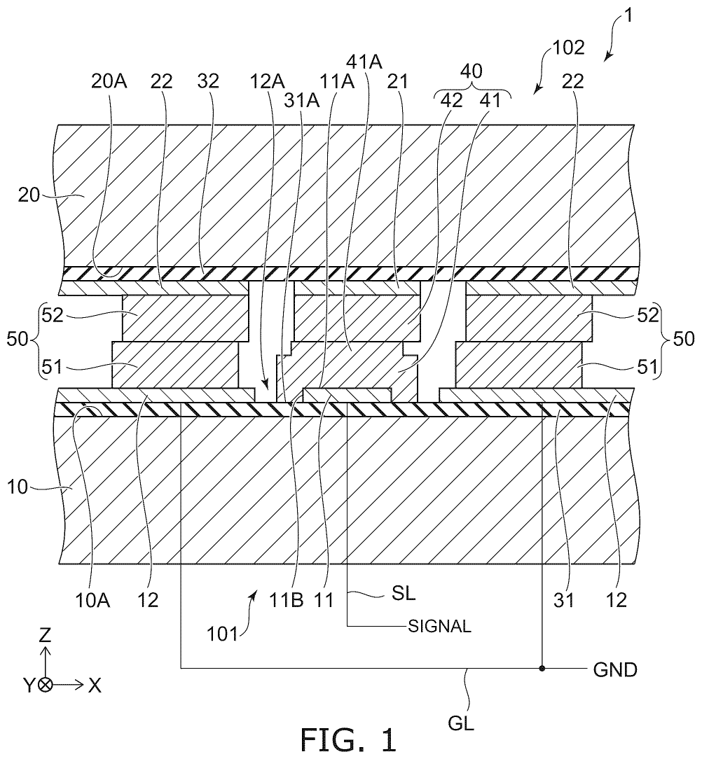

As shown in FIG. 1, a chip-stacked device 1 according to a first embodiment includes a first chip 101 and a second chip 102. The first chip 101 and the second chip 102 are stacked in a first direction Z. Two directions orthogonal to each other in a plane orthogonal to the first direction Z are defined as a second direction X and a third direction Y.

The first chip 101 includes a first substrate 10 including a first face 10A, a first conductive film 11 provided on the first face 10A, and a second conductive film 12 provided on the first face 10A. The first substrate 10 is, for example, a silicon substrate. The first chip 101 further includes a first insulating film 31 provided on the first face 10A. The first insulating film 31 is, for example, a silicon oxide film. The first conductive film 11 and the second conductive film 12 are provided on the first insulating film 31. When the first substrate 10 has insulating properties, the first insulating film 31 need not be provided, and the first conductive film 11 and the second conductive film 12 may be provided directly on the first face 10A. The first conductive film 11 and the second conductive film 12 are, for example, titanium nitride films.

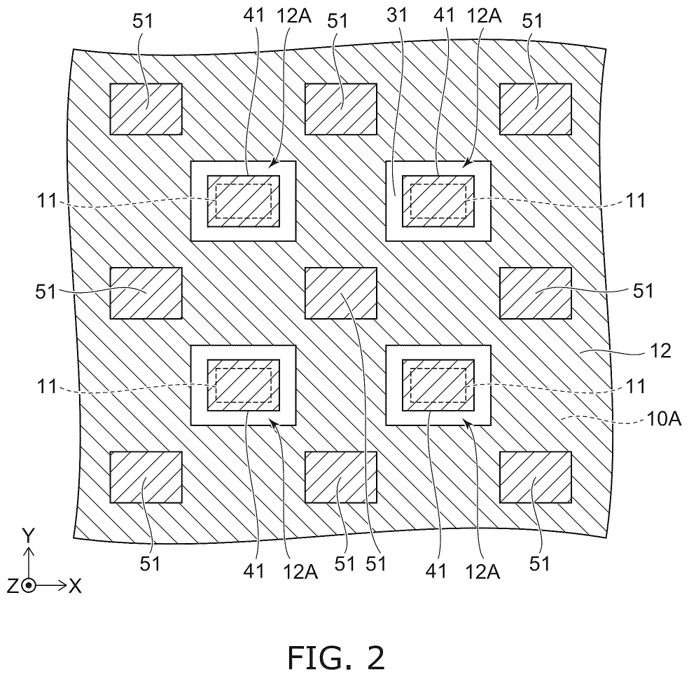

FIG. 2 is a schematic plan view of the first face 10A side of the first substrate 10. FIG. 2 shows an example arrangement relationship among the first conductive film 11, the second conductive film 12, a first metal portion 41 of a first bonding portion 40, which will be described below, and a third metal portion 51 of a second bonding portion 50, which will be described below.

A plurality of first conductive films 11 are arranged side by side and apart from each other in the second direction X and the third direction Y. For example, the second conductive film 12 extends on the first face 10A over an area larger than the total area of the plurality of first conductive films 11. The first conductive film 11 is provided in an island form in a first opening 12A formed in the second conductive film 12, and is apart from the second conductive film 12.

The second chip 102 includes a second substrate 20 including a second face 20A, a third conductive film 21 provided on the second face 20A, and a fourth conductive film 22 provided on the second face 20A. The second face 20A of the second substrate 20 faces the first face 10A of the first substrate 10 in the first direction Z. The second substrate 20 is, for example, a silicon substrate. The second chip 102 further includes a second insulating film 32 provided on the second face 20A. The second insulating film 32 is, for example, a silicon oxide film. The third conductive film 21 and the fourth conductive film 22 are provided on the second insulating film 32 and are separated from each other. When the second substrate 20 has insulating properties, the second insulating film 32 need not be provided, and the third conductive film 21 and the fourth conductive film 22 may be provided directly on the second face 20A. The third conductive film 21 and the fourth conductive film 22 are, for example, titanium nitride films.

As shown in FIG. 1, the chip-stacked device 1 further includes a plurality of first bonding portions 40 and a plurality of second bonding portions 50 provided between the first chip 101 and the second chip 102 in the first direction Z. The first chip 101 and the second chip 102 are bonded to each other via the plurality of first bonding portions 40 and the plurality of second bonding portions 50.

The first bonding portion 40 includes the first metal portion 41 provided on the first chip 101 side, and a second metal portion 42 located between the first metal portion 41 and the second chip 102 in the first direction Z and bonded to the first metal portion 41. The second bonding portion 50 includes the third metal portion 51 provided on the first chip 101 side, and a fourth metal portion 52 located between the third metal portion 51 and the second chip 102 in the first direction Z and bonded to the third metal portion 51. The first metal portion 41 and the second metal portion 42 include, for example, gold, and the first bonding portion 40 is a gold-to-gold bonded body. The third metal portion 51 and the fourth metal portion 52 include, for example, gold, and the second bonding portion 50 is a gold-to-gold bonded body.

A plurality of fourth metal portions 52 on the second chip 102 side are connected to the common fourth conductive film 22 provided on the second face 20A of the second substrate 20. A plurality of third conductive films 21 corresponding to the number of the plurality of first bonding portions 40 are provided apart from each other on the second face 20A.

The second conductive film 12 of the first chip 101 is provided on the entire face, of the second bonding portion 50, facing the first face 10A of the first substrate 10 (the lower face of the third metal portion 51 in FIG. 1), and is electrically connected to the second bonding portion 50. As shown in FIG. 2, a plurality of third metal portions 51 are connected onto the common second conductive film 12 extending on the first face 10A. The second bonding portion 50 is apart from the first conductive film 11 and the first bonding portion 40 and is located on the second conductive film 12.

The first conductive film 11 is provided on a part of a face, of the first bonding portion 40, facing the first face 10A of the first substrate 10 (the lower face of the first metal portion 41 in FIG. 1), and is electrically connected to the first bonding portion 40. As shown in FIG. 2, in plan view, the first metal portion 41 is located on the first conductive film 11 in the first opening 12A formed in the second conductive film 12. In plan view, the outer edge (depicted in a dashed line) of the first conductive film 11 is located inside the outer edge (depicted in a solid line) of the first metal portion 41 of the first bonding portion 40. The first bonding portion 40 covers a surface 11A (the upper face in FIG. 1), of the first conductive film 11, facing the second chip 102 and a side face 11B of the first conductive film 11 in the first opening 12A.

As shown in FIG. 1, the first conductive film 11 is not provided on a part other than the above-described part of the face, of the first bonding portion 40, facing the first face 10A. A part of the first bonding portion 40 is in contact with the first insulating film 31. The first bonding portion 40 covers a step portion between a surface 31A (a face facing the second chip 102) of the first insulating film 31 and the surface 11A of the first conductive film 11. The first metal portion 41 of the first bonding portion 40 covers the first conductive film 11 so as to cover the step portion between the surface 11A of the first conductive film 11 provided between the first bonding portion 40 and the first face 10A and the surface 31A of the first insulating film 31. Due to the presence of the above-described step portion, a step portion is also formed on a bonding face, of the first metal portion 41, bonded to the second metal portion 42, and a first protruding portion 41A is formed on the bonding face, of the first metal portion 41, bonded to the second metal portion 42. The width of the first protruding portion 41A in the second direction X is larger than the width of the first conductive film 11 in the second direction X.

The first metal portion 41 is bonded to the second metal portion 42 at least at the first protruding portion 41A. The bonding face, of the third metal portion 51 of the second bonding portion 50, bonded to the fourth metal portion 52 has higher flatness (smaller step) than the above-described bonding face, of the first metal portion 41, on which the first protruding portion 41A is formed. The first metal portion 41 and the second metal portion 42 are bonded to each other via the first protruding portion 41A, and the third metal portion 51 and the fourth metal portion 52 are bonded to each other by bonding faces having higher flatness than the first bonding portion 40. For example, the bonding area between the first metal portion 41 and the second metal portion 42 is smaller than the bonding area between the third metal portion 51 and the fourth metal portion 52.

Each of the plurality of first conductive films 11 is electrically connected to a signal line SL, and each of the plurality of first bonding portions 40 is electrically connected to the signal line SL via the first conductive film 11. The third conductive film 21 of the second chip 102 is electrically connected to the signal line SL via the first bonding portion 40 and the first conductive film 11. The signal line SL, the first conductive film 11, the first bonding portion 40, and the third conductive film 21 are electrically connected to form a signal system. For example, the plurality of first bonding portions 40 are connected to different signal lines SL, and the potentials of the plurality of signal systems can be controlled independently of each other.

The second conductive film 12 is electrically connected to a ground line GL. The plurality of second bonding portions 50 are electrically connected to the ground line GL via the common second conductive film 12. The fourth conductive film 22 of the second chip 102 is electrically connected to the ground line GL via the second bonding portion 50 and the second conductive film 12. A ground potential can be applied to the fourth conductive film 22 via the ground line GL, the second conductive film 12, and the second bonding portion 50. The ground line GL may be a wiring layer to which the ground potential applied.

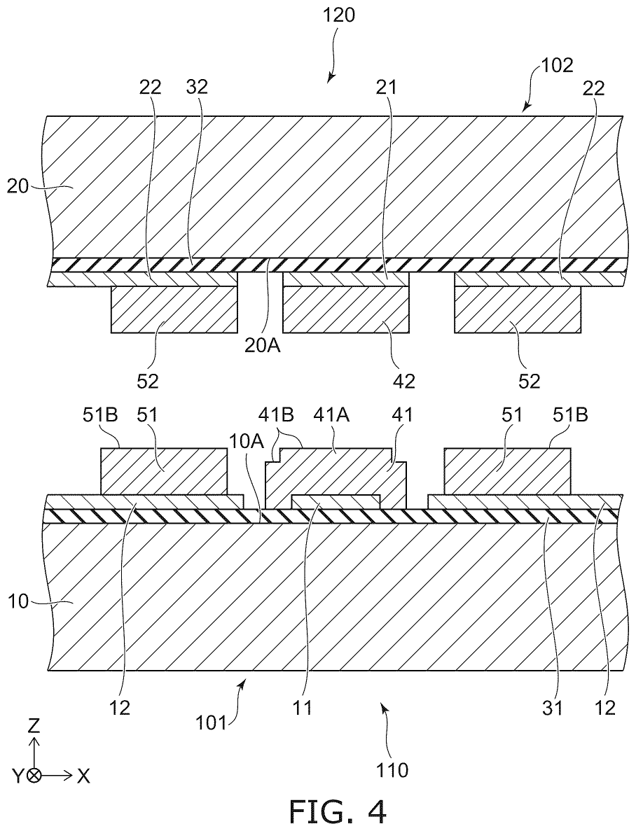

A method for manufacturing the chip-stacked device 1 according to the first embodiment will now be described with reference to FIG. 4.

The method for manufacturing the chip-stacked device 1 according to the first embodiment includes a process of preparing a first structure 110 and a process of preparing a second structure 120.

The first structure 110 has a configuration in which the first metal portion 41 is connected to the first conductive film 11 and the third metal portion 51 is connected to the second conductive film 12 in the first chip 101 described above. The second structure 120 has a configuration in which the second metal portion 42 is connected to the third conductive film 21 and the fourth metal portion 52 is connected to the fourth conductive film 22 in the second chip 102 described above.

The method for manufacturing the chip-stacked device 1 according to the first embodiment includes a process of bonding the first metal portion 41 and the second metal portion 42 and bonding the third metal portion 51 and the fourth metal portion 52 by causing the first face 10A of the first substrate 10 and the second face 20A of the second substrate 20 to face each other in the first direction Z and applying a load in the first direction Z to the first structure 110 and the second structure 120.

The first metal portion 41 and the second metal portion 42 are directly bonded to each other by bringing the first metal portion 41 and the second metal portion 42 into contact with each other, applying a load in the first direction Z to the first metal portion 41 and the second metal portion 42, and heating the first metal portion 41 and the second metal portion 42, and the first bonding portion 40 shown in FIG. 1 is formed. The third metal portion 51 and the fourth metal portion 52 are directly bonded to each other by bringing the third metal portion 51 and the fourth metal portion 52 into contact with each other, applying a load in the first direction Z to the third metal portion 51 and the fourth metal portion 52, and heating the third metal portion 51 and the fourth metal portion 52, and the second bonding portion 50 shown in FIG. 1 is formed.

A protruding portion is provided on a first bonding face, of at least one of the first metal portion 41 and the second metal portion 42, bonded to the other metal portion. Further, a step on a second bonding face, of at least one of the third metal portion 51 and the fourth metal portion 52, bonded to the other metal portion is smaller than a step on the first bonding face on which the protruding portion is provided.

According to the embodiment, the first protruding portion 41A is provided on a first bonding face 41B, of the first metal portion 41, bonded to the second metal portion 42. Since the first protruding portion 41A is provided, compared to a case where the first protruding portion 41A is not provided on the first bonding face 41B of the first metal portion 41, the contact area between the first metal portion 41 and the second metal portion 42 at the time of bonding in which a load is applied in the first direction Z can be reduced and the pressure applied to the bonding face between the first metal portion 41 and the second metal portion 42 can be increased. Accordingly, the first metal portion 41 and the second metal portion 42 can be bonded to each other with certainty, and a signal of the signal line SL can be supplied from the first chip 101 side to the second chip 102 side with certainty.

Further, the step on a second bonding face 51B, of the third metal portion 51, bonded to the fourth metal portion 52 is smaller than the step on the first bonding face 41B of the first metal portion 41. Accordingly, the bonding area between the third metal portion 51 and the fourth metal portion 52 per second bonding portion 50 can be made larger than the bonding area between the first metal portion 41 and the second metal portion 42 per first bonding portion 40, and the bonding strength between the first chip 101 and the second chip 102 can be increased.

The pressure applied to the bonding face, between the third metal portion 51 and the fourth metal portion 52, without a protruding portion is lower than the pressure applied to the bonding face between the first metal portion 41 and the second metal portion 42, and the bondability in the second bonding portion 50 is likely to be lower than the bondability in the first bonding portion 40. However, since the plurality of second bonding portions 50 are connected in common to the second conductive film 12 of the first chip 101 and are connected in common to the fourth conductive film 22 of the second chip 102, the ground potential can be applied to the fourth conductive film 22 of the second chip 102 from the first chip 101 side as long as any of the plurality of second bonding portions 50 can be bonded with certainty.

According to the embodiment, both the bondability between the first metal portion 41 and the second metal portion 42 used in the signal system and the bonding strength resulting from the increased bonding area between the first chip 101 and the second chip 102 can be attained.

As shown in FIG. 2, in plan view, the number of the third metal portions 51 of the second bonding portions 50 disposed around the first metal portion 41 of one first bonding portion 40 is the same as the number of the first metal portions 41 of the first bonding portions 40 disposed around the third metal portion 51 of one second bonding portion 50. For example, four third metal portions 51 are disposed around one first metal portion 41, and four first metal portions 41 are disposed around one third metal portion 51. Accordingly, the bonding area is not imbalanced between the first chip 101 and the second chip 102, and the first chip 101 and the second chip 102 can maintain uniform bonding strength in a plane parallel to the X-Y plane.

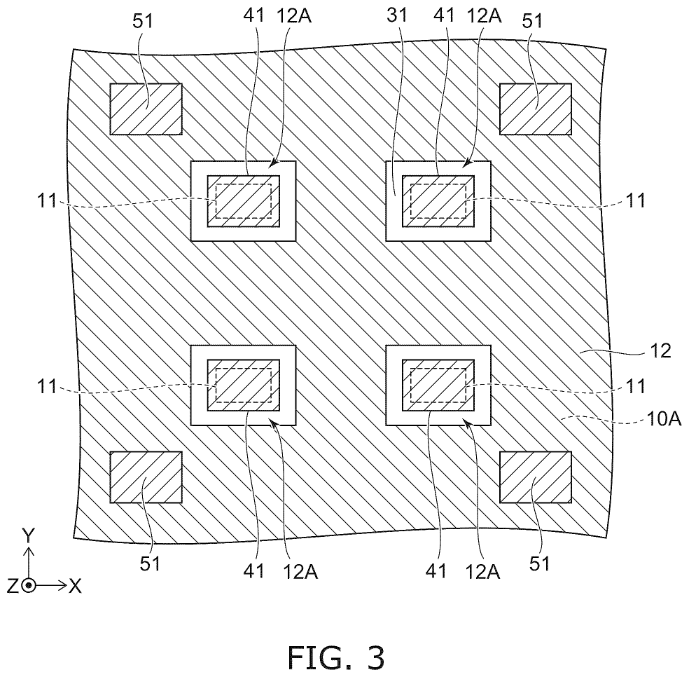

As shown in FIG. 3, the number of the third metal portions 51 of a ground system can be reduced. Accordingly, the entire bonding area between the first chip 101 and the second chip 102 can be adjusted, and the bonding pressure can be adjusted.

### Second Embodiment

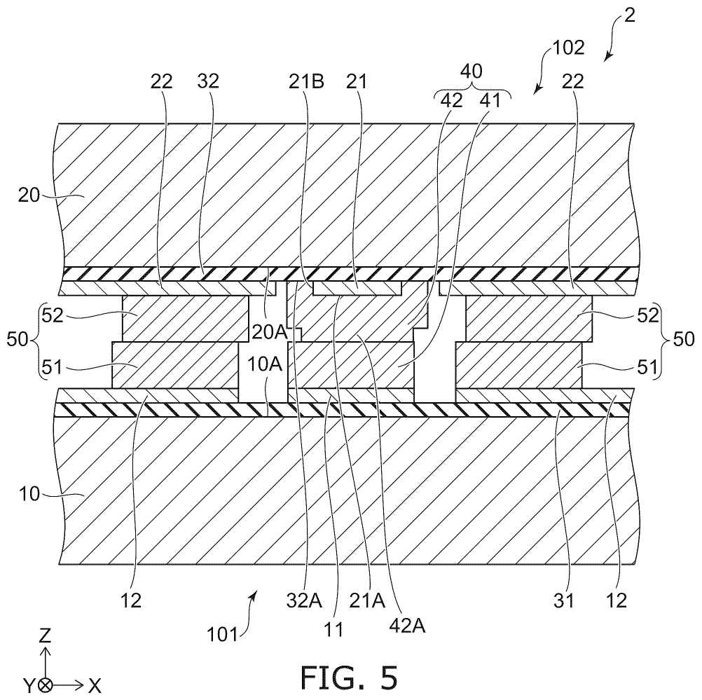

FIG. 5 is a schematic cross-sectional view of a chip-stacked device 2 according to a second embodiment.

The third conductive film 21 of the second chip 102 of the chip-stacked device 2 is provided on a part of a face, of the first bonding portion 40, facing the second face 20A of the second substrate 20, and is electrically connected to the first bonding portion 40. The third conductive film 21 is not provided on a part other than the above-described part of the face, of the first bonding portion 40, facing the second face 20A. The first bonding portion 40 covers a surface 21A (the lower face in FIG. 5), of the third conductive film 21, facing the first chip 101 and a side face 21B of the third conductive film 21. A part of the first bonding portion 40 is in contact with the second insulating film 32. The first bonding portion 40 covers a step portion between a surface 32A (a face facing the first chip 101) of the second insulating film 32 and the surface 21A of the third conductive film 21. The second metal portion 42 of the first bonding portion 40 covers the third conductive film 21 so as to cover the step portion between the surface 21A of the third conductive film 21 provided between the first bonding portion 40 and the second face 20A and the surface 32A of the second insulating film 32. Due to the presence of the above-described step portion, a step portion is also formed on a bonding face, of the second metal portion 42, bonded to the first metal portion 41, and a second protruding portion 42A is formed on the bonding face, of the second metal portion 42, bonded to the first metal portion 41. The width of the second protruding portion 42A in the second direction X is larger than the width of the third conductive film 21 in the second direction X.

The second metal portion 42 is bonded to the first metal portion 41 at least at the second protruding portion 42A. The first metal portion 41 and the second metal portion 42 are bonded to each other via the second protruding portion 42A. Since the second protruding portion 42A is provided on the second metal portion 42, compared to a case where the second protruding portion 42A is not provided, the pressure applied to the bonding face between the first metal portion 41 and the second metal portion 42 at the time of bonding in which a load is applied in the first direction Z can be increased. Accordingly, the first metal portion 41 and the second metal portion 42 can be bonded to each other with certainty, and a signal of the signal line SL can be supplied from the first chip 101 side to the second chip 102 side with certainty.

The bonding face, of the fourth metal portion 52 of the second bonding portion 50 electrically connected to the ground line GL, bonded to the third metal portion 51 has higher flatness (smaller step) than the bonding face, of the second metal portion 42, on which the second protruding portion 42A is formed. The third metal portion 51 and the fourth metal portion 52 are bonded to each other by bonding faces having higher flatness than the first bonding portion 40. Accordingly, the bonding area between the third metal portion 51 and the fourth metal portion 52 per second bonding portion 50 can be made larger than the bonding area between the first metal portion 41 and the second metal portion 42 per first bonding portion 40, and the bonding strength between the first chip 101 and the second chip 102 can be increased.

### Third Embodiment

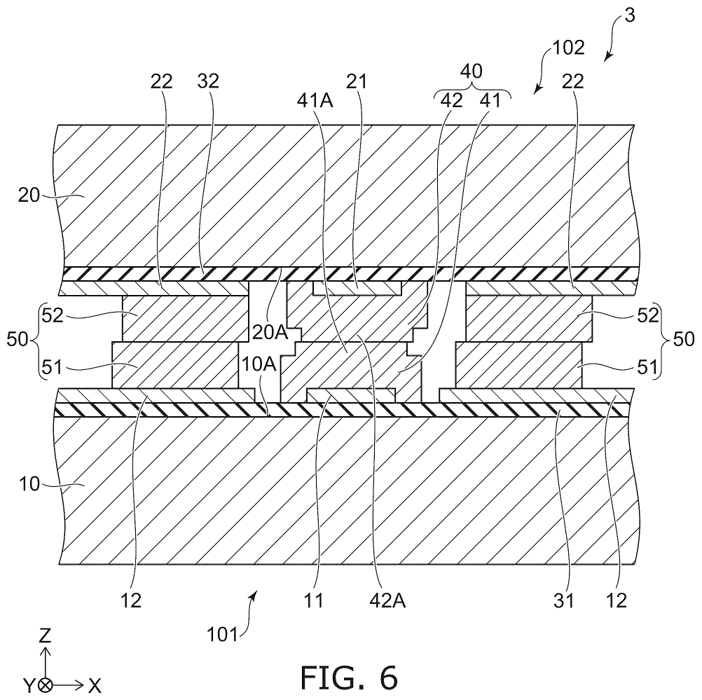

FIG. 6 is a schematic cross-sectional view of a chip-stacked device 3 according to a third embodiment.

The chip-stacked device 3 according to the third embodiment has a configuration that is a combination of the chip-stacked device 1 according to the first embodiment and the chip-stacked device 2 according to the second embodiment.

That is, the first metal portion 41 and the second metal portion 42 are bonded to each other via the first protruding portion 41A and the second protruding portion 42A. At least the first protruding portion 41A and the second protruding portion 42A are bonded to each other. Accordingly, the pressure applied to the bonding face between the first metal portion 41 and the second metal portion 42 at the time of bonding in which a load is applied in the first direction Z can be increased, and the first metal portion 41 and the second metal portion 42 can be bonded to each other with certainty.

Further, the third metal portion 51 and the fourth metal portion 52 are bonded to each other by bonding faces having higher flatness than the first bonding portion 40. Accordingly, the bonding area between the third metal portion 51 and the fourth metal portion 52 per second bonding portion 50 can be made larger than the bonding area between the first metal portion 41 and the second metal portion 42 per first bonding portion 40, and the bonding strength between the first chip 101 and the second chip 102 can be increased.

### Fourth Embodiment

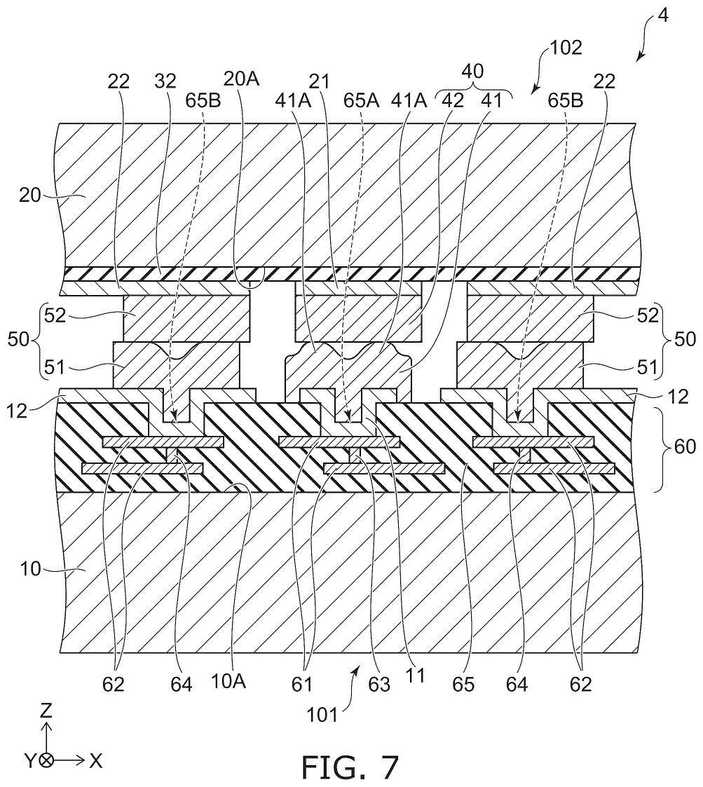

FIG. 7 is a schematic cross-sectional view of a chip-stacked device 4 according to a fourth embodiment.

The first chip 101 in the chip-stacked device 4 includes a wiring portion 60 provided on the first face 10A of the first substrate 10. The wiring portion 60 includes an insulating layer 65 provided on the first face 10A of the first substrate 10, a first wiring layer 61 provided in the insulating layer 65, and a second wiring layer 62 provided in the insulating layer 65 separately from the first wiring layer 61.

The wiring portion 60 is a wiring portion having a multilayer wiring structure that includes at least first wiring layers 61 in two layers and at least second wiring layers 62 in two layers. The first wiring layers 61 in different layers are electrically connected to each other by a first conductive via 63. The second wiring layers 62 in different layers are electrically connected to each other by a second conductive via 64.

The first conductive film 11 is provided on the surface of the insulating layer 65 and in a first connection hole 65A reaching the first wiring layer 61 from the surface of the insulating layer 65, and is connected to the first wiring layer 61. The first wiring layer 61 is, for example, a signal line.

The first bonding portion 40 is connected to the first conductive film 11 on the surface of the insulating layer 65 and is also connected to the first conductive film 11 in the first connection hole 65A. The first bonding portion 40 is electrically connected to the first wiring layer 61 via the first conductive film 11.

The second conductive film 12 is provided on the surface of the insulating layer 65 and in a second connection hole 65B reaching the second wiring layer 62 from the surface of the insulating layer 65, and is connected to the second wiring layer 62. The second wiring layer 62 is, for example, a ground line.

The second bonding portion 50 is connected to the second conductive film 12 on the surface of the insulating layer 65 and is also connected to the second conductive film 12 in the second connection hole 65B. The second bonding portion 50 is electrically connected to the second wiring layer 62 via the second conductive film 12.

The first conductive film 11 is provided on a part of a face, of the first bonding portion 40, facing the first face 10A. The first conductive film 11 is not provided on a part other than the above-described part of the face, of the first bonding portion 40, facing the first face 10A. The first metal portion 41 of the first bonding portion 40 covers the first conductive film 11 so as to cover the step between the first conductive film 11 and the insulating layer 65. Due to the presence of the above-described step, a step is also formed on the bonding face, of the first metal portion 41, bonded to the second metal portion 42, and the first protruding portion 41A is formed on the bonding face, of the first metal portion 41, bonded to the second metal portion 42.

The first metal portion 41 is bonded to the second metal portion 42 at least at the first protruding portion 41A. Accordingly, the pressure applied to the bonding face between the first metal portion 41 and the second metal portion 42 at the time of bonding in which a load is applied in the first direction Z can be increased, and the first metal portion 41 and the second metal portion 42 can be bonded to each other with certainty.

The bonding face, of the third metal portion 51 of the second bonding portion 50, bonded to the fourth metal portion 52 has higher flatness (smaller step) than the bonding face, of the first metal portion 41, on which the first protruding portion 41A is formed. The third metal portion 51 and the fourth metal portion 52 are bonded to each other by bonding faces having higher flatness than the first bonding portion 40. Accordingly, the bonding area between the third metal portion 51 and the fourth metal portion 52 per second bonding portion 50 can be made larger than the bonding area between the first metal portion 41 and the second metal portion 42 per first bonding portion 40, and the bonding strength between the first chip 101 and the second chip 102 can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A chip-stacked device comprising:
a first chip including a first substrate including a first face, a first conductive film provided in an island form over the first face and electrically connected to a signal line, and a second conductive film provided apart from the first conductive film over the first face and connected to the ground line;
a second chip;
a first bonding portion covering the first conductive film; and
a second bonding portion apart from the first conductive film and the first bonding portion, the second bonding portion located over the second conductive film;
wherein the first chip and the second chip are bonded to each other via the first bonding portion and the second bonding portion.

2. The chip-stacked device according to claim 1, wherein
the first chip further includes a first insulating film provided on the first face of the first substrate,
the first conductive film and the second conductive film are provided on the first insulating film,
a part of the first bonding portion is in contact with the first insulating film, and
the first bonding portion covers a step portion between a surface of the first insulating film and a surface of the first conductive film.

3. The chip-stacked device according to claim 1, wherein
the second chip includes
a second substrate including a second face facing the first face of the first substrate,
a third conductive film provided in an island form over the second face, and
a fourth conductive film provided apart from the third conductive film over the second face,
the first bonding portion covers the third conductive film, and
the second bonding portion is apart from the third conductive film and the first bonding portion and is located on the fourth conductive film.

4. The chip-stacked device according to claim 1, wherein
the first bonding portion includes a first metal portion and a second metal portion located between the first metal portion and the second chip and bonded to the first metal portion,
the second bonding portion includes a third metal portion and a fourth metal portion located between the third metal portion and the second chip and bonded to the third metal portion, and
a bonding area between the first metal portion and the second metal portion is smaller than a bonding area between the third metal portion and the fourth metal portion.

5. The chip-stacked device according to claim 1, wherein
the first chip includes an insulating layer provided on the first face of the first substrate, a first wiring layer provided in the insulating layer, and a second wiring layer provided in the insulating layer,
the first conductive film is provided on a surface of the insulating layer and in a first connection hole reaching the first wiring layer from the surface of the insulating layer, and is connected to the first wiring layer,
the first bonding portion is connected to the first conductive film on the surface of the insulating layer and is connected to the first conductive film in the first connection hole,
the second conductive film is provided on the surface of the insulating layer and in a second connection hole reaching the second wiring layer from the surface of the insulating layer, and is connected to the second wiring layer, and
the second bonding portion is connected to the second conductive film on the surface of the insulating layer and is connected to the second conductive film in the second connection hole.

6. A chip-stacked device comprising:
a first chip;
a second chip including a second substrate including a second face, a third conductive film provided in an island form over the second face and electrically connected to the signal line, and a fourth conductive film provided apart from the third conductive film over the second face and connected to the ground line;
a first bonding portion covering the third conductive film; and
a second bonding portion apart from the third conductive film and the first bonding portion, the second bonding portion located over the fourth conductive film;
wherein the first chip and the second chip are bonded to each other via the first bonding portion and the second bonding portion.

7. The chip-stacked device according to claim 6, wherein
the second chip further includes a second insulating film provided over the second face of the second substrate,
the third conductive film and the fourth conductive film are provided over the second insulating film,
a part of the first bonding portion is in contact with the second insulating film, and
the first bonding portion covers a step portion between a surface of the second insulating film and a surface of the third conductive film.

8. The chip-stacked device according to claim 6, wherein
the first bonding portion includes a first metal portion and a second metal portion located between the first metal portion and the second chip and bonded to the first metal portion,
the second bonding portion includes a third metal portion and a fourth metal portion located between the third metal portion and the second chip and bonded to the third metal portion, and
a bonding area between the first metal portion and the second metal portion is smaller than a bonding area between the third metal portion and the fourth metal portion.

9. The chip-stacked device according to claim 6, wherein
the first chip includes
a first substrate including a first face,
an insulating layer provided on the first face of the first substrate,
a first wiring layer provided in the insulating layer,
a second wiring layer provided in the insulating layer,
a first conductive film provided in an island form on the first face and electrically connected to the signal line, and
a second conductive film provided apart from the first conductive film on the first face and connected to the ground line,
the first conductive film is provided on a surface of the insulating layer and in a first connection hole reaching the first wiring layer from the surface of the insulating layer, and is connected to the first wiring layer,
the first bonding portion is connected to the first conductive film on the surface of the insulating layer and is connected to the first conductive film in the first connection hole,
the second conductive film is provided on the surface of the insulating layer and in a second connection hole reaching the second wiring layer from the surface of the insulating layer, and is connected to the second wiring layer, and
the second bonding portion is connected to the second conductive film on the surface of the insulating layer and is connected to the second conductive film in the second connection hole.

10. A method for manufacturing a chip-stacked device, comprising:
preparing a first structure in which a plurality of first metal portions electrically connected to a signal line and a plurality of third metal portions electrically connected to a ground line are provided on a first face of a first substrate;
preparing a second structure in which a plurality of second metal portions and a plurality of fourth metal portions are provided on a second face of a second substrate; and
bonding the first metal portion and the second metal portion to each other and bonding the third metal portion and the fourth metal portion to each other by causing the first face and the second face to face each other in a first direction and applying a load in the first direction to the first structure and the second structure,
a protruding portion being provided on a first bonding face of at least one of the first metal portion and the second metal portion, the first bonding face being bonded to another of the first metal portion and the second metal portion,
a step on a second bonding face of at least one of the third metal portion and the fourth metal portion, the second bonding face being bonded to another of the third metal portion and the fourth metal portion, being smaller than a step on the first bonding face.
